(19) United States
(12) Patent Application Publication
(10) Pub. No.: US 2019/0043696 A1
(43) Pub. Date: Feb. 7, 2019

(54) FLOW GUIDE PLATE, LOWER ELECTRODE ASSEMBLY FOR DRY ETCHING APPARATUS, AND DRY ETCHING APPARATUS

(71) Applicants: BOE TECHNOLOGY GROUP CO., LTD., Beijing (CN); Chengdu BOE Optoelectronics Technology Co., Ltd., Chengdu (CN)

(72) Inventors: Kai Jiang, Beijing (CN); Xiaofeng Yang, Beijing (CN); Mingzhi Chai, Beijing (CN); Shihong Chen, Beijing (CN); Zhong Yang, Beijing (CN); Zelin Chen, Beijing (CN)

(21) Appl. No.: 15/967,213

(22) Filed: Apr. 30, 2018

(30) Foreign Application Priority Data
Aug. 2, 2017 (CN) 201720961352.2

(51) Int. Cl. H01J 37/32

(52) U.S. Cl. CPC H01J 37/32449; H01J 2237/334; H01J 37/32568

(57) ABSTRACT

Embodiments of the present disclosure provide a flow guide plate, a lower electrode assembly for a dry etching apparatus, and a dry etching apparatus. The flow guide plate includes a body and a gas flow passage which is formed in the body and through which a gas flow passes. At least a portion of the gas flow passage is located between a first position and a second position of the body, and a passage area per unit length of at least the portion of the gas flow passage is gradually increased in a direction from the first position to the second position.

### CROSS-REFERENCE TO RELATED APPLICATION(S)

This application claims the benefit of Chinese Patent Application No. 201720961352.2, filed with the State Intellectual Property Office of China on Aug. 2, 2017, the whole disclosure of which is incorporated herein by reference.

BACKGROUND

### 1. Technical Field

The present disclosure relates to a flow guide plate, a lower electrode assembly for a dry etching apparatus and a dry etching apparatus.

### 2. Description of the Related Art

Generally, a display device is manufactured by a dry etching apparatus. A dry etching apparatus in related art comprises a reaction chamber, and an upper electrode and a lower electrode which are located inside the reaction chamber. A substrate to be etched is placed on the lower electrode. After processing gas is fed into the reaction chamber, a voltage is applied to the upper electrode and the lower electrode so that an electric potential difference is formed between them. Under the action of an electric field, the processing gas reacts to generate plasmas. The plasmas having high energy bombard the substrate at a high velocity, thereby etching the substrate.

### SUMMARY

Embodiments of the present disclosure provide a flow guide plate comprising: a body; and a gas flow passage which is formed in the body and through which a gas flow passes, wherein at least a portion of the gas flow passage is located between a first position and a second position of the body, and a passage area per unit length of at least the portion of the gas flow passage is gradually increased in a direction from the first position to the second position.

According to embodiments of the present disclosure, the gas flow passage comprises a plurality of through holes.

According to embodiments of the present disclosure, the body is a strip-shaped flat plate, and the first position and the second position are positions of the body in a length direction of the body.

According to embodiments of the present disclosure, wherein a ratio of the passage area per unit length of at least the portion of the gas flow passage formed in the body to a total passage area of the plurality of through holes is gradually increased in the direction from the first position to the second position.

According to embodiments of the present disclosure, the plurality of through holes have a same diameter, and a distribution density of the through holes per unit length of at least the portion of the gas flow passage formed in the body is gradually increased in the direction from the first position to the second position.

According to embodiments of the present disclosure, the plurality of through holes are arranged in one row along the length direction of the body, and a number of through holes per unit length of at least the portion of the gas flow passage formed in the body is gradually increased in the direction from the first position to the second position.

According to embodiments of the present disclosure, the plurality of through holes are arranged in a plurality of rows along the length direction of the body, and a number of rows of through holes per unit length of at least the portion of the gas flow passage formed in the body is gradually increased in the direction from the first position to the second position.

According to embodiments of the present disclosure, a distribution density per unit length of the plurality of through holes in the body is uniform, and diameters of through holes of at least the portion of the gas flow passage formed in the body are gradually increased in the direction from the first position to the second position.

According to embodiments of the present disclosure, the plurality of through holes are arranged in a plurality of rows along the length direction of the body, a number of rows of through holes per unit length of at least the portion of the gas flow passage formed in the body is gradually increased in the direction from the first position to the second position, and diameters of through holes of at least the portion of the gas flow passage formed in the body are gradually increased in the direction from the first position to the second position.

According to embodiments of the present disclosure, the first position is a center of the body, and the second position is two ends of the body in the length direction of the body.

Embodiments of the present disclosure also provide a lower electrode assembly for a dry etching apparatus, the lower electrode assembly comprising: a lower electrode; and the above flow guide plate connected to a side of the lower electrode.

According to embodiments of the present disclosure, the flow guide plate comprises four flow guide plate respectively disposed on four sides of the lower electrode.

Embodiments of the present disclosure also provide a dry etching apparatus comprising: a housing defining a reaction chamber; and the above lower electrode assembly disposed inside the reaction chamber.

According to embodiments of the present disclosure, the dry etching apparatus further comprises: a gas suction opening formed in a bottom wall of the housing at a central position of a side of the bottom wall.

According to embodiments of the present disclosure, the bottom wall has a substantially polygonal shape, and has a plurality of sides, and the body is a strip-shaped flat plate.

According to embodiments of the present disclosure, the bottom wall of the housing is formed with the gas suction opening at a first one of the plurality of sides of the bottom wall, and is formed with no gas suction opening at a second one of the plurality of sides of the bottom wall; and in the lower electrode assembly of the dry etching apparatus, a passage area per unit length of the gas flow passage formed in the body of the flow guide plate corresponding to the first one of the plurality of sides is less than a passage area per unit length of the gas flow passage formed in the body of the flow guide plate corresponding to the second one of the plurality of sides.

### BRIEF DESCRIPTION OF THE DRAWINGS

In order to describe technical solutions in embodiments of the present disclosure more clearly, accompanying drawings required for describing the embodiments will be simply explained as below. Apparently, the accompanying drawings for the following description are only some embodiments of the present disclosure. Those skilled in the art also could derive other accompanying drawings from these accompanying drawings without making a creative work.

FIG. 1 is a schematic view showing a structure of a flow guide plate according to an embodiment of the present disclosure;

FIG. 2 is a schematic view showing a structure of a lower electrode assembly for a dry etching apparatus according to an embodiment of the present disclosure;

FIG. 3 is a schematic view showing a structure of a flow guide plate having a plurality of through holes and having a flat plate shape, according to an embodiment of the present disclosure;

FIG. 4 is a schematic view showing a structure of a flow guide plate having a plurality of through holes and having a flat plate shape, according to another embodiment of the present disclosure;

FIG. 5 is a schematic view showing a structure of a flow guide plate having a plurality of through holes and having a flat plate shape, according to a further embodiment of the present disclosure;

FIG. 6 is a schematic view showing a structure of a flow guide plate having a plurality of through holes and having a flat plate shape, according to a still another embodiment of the present disclosure;

FIG. 7 is a left view of the lower electrode assembly shown in FIG. 2;

FIG. 8 is a schematic view showing a structure of a lower electrode assembly for a dry etching apparatus according to an embodiment of the present disclosure, in which a flow guide plate is disposed on each of four sides of a lower electrode in the lower electrode assembly;

FIG. 9 is a schematic view showing a structure of a dry etching apparatus according to an embodiment of the present disclosure;

FIG. 10 is a sectional view taken along the line B-B in FIG. 9 and showing a dry etching apparatus according to an embodiment of the present disclosure;

FIG. 11 is a sectional view taken along the line B-B in FIG. 9 and showing a dry etching apparatus according to another embodiment of the present disclosure; and

FIG. 12 is a sectional view taken along the line B-B in FIG. 9 and showing a dry etching apparatus according to still another embodiment of the present disclosure.

### DETAILED DESCRIPTION OF THE EMBODIMENTS

A clear and complete description of technical solutions in embodiments of the present disclosure will be made as below in conjunction with the accompanying drawings in the embodiments of the present disclosure. Apparently, the described embodiments are some of the embodiments of the present disclosure rather than all of the embodiments of the present disclosure. All other embodiments derived by those skilled in the art based on the embodiments of the present disclosure without making a creative work shall fall within the protection scope of the present disclosure.

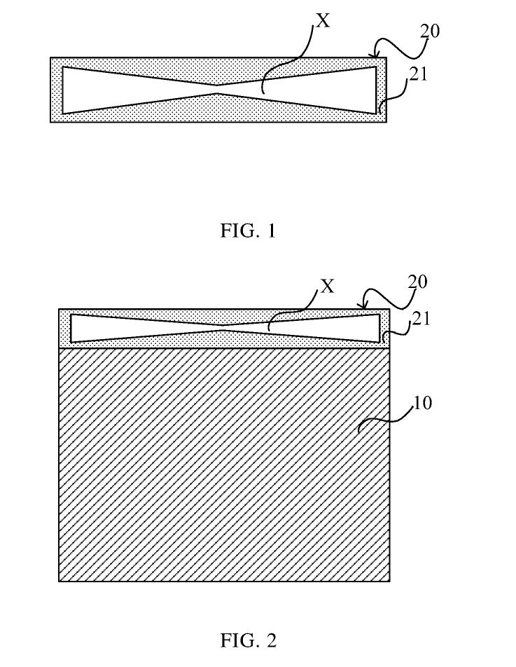

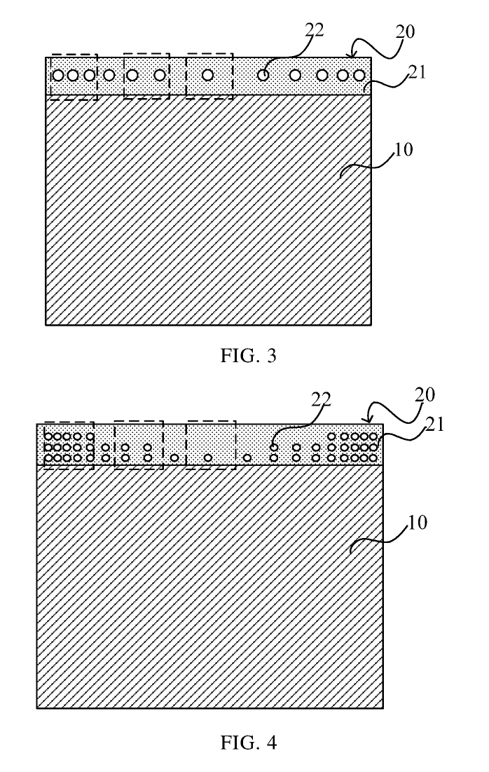

Embodiments of the present disclosure provide a flow guide plate 20. Referring to FIG. 1, the flow guide plate 20 comprises: a body 21; and a gas flow passage X which is formed in the body 21 and through which a gas flow passes. At least a portion of the gas flow passage X is located between a first position and a second position of the body 21, and a passage area per unit length of at least the portion of the gas flow passage X is gradually increased in a direction from the first position to the second position. The flow guide plate according to the embodiments of the present disclosure is applicable to a dry etching apparatus. As shown in FIG. 2, the flow guide plate 20 is disposed on a side of a lower electrode 10 of the dry etching apparatus. In order to clearly show a direction and a position of the flow guide plate 20 in a lower electrode assembly of the dry etching apparatus, the drawings for the flow guide plate 20 to be described as below all show the flow guide plate 20 together with the lower electrode 10 of the dry etching apparatus in which the flow guide plate is disposed.

The flow guide plate 20 according to the embodiments of the present disclosure is connected to a side of the lower electrode 10 of the dry etching apparatus. When a substrate is dry-etched by the dry etching apparatus, a gas flow is blown to the flow guide plate 20. A portion of the gas flow blown to the gas flow passage X passes through the gas flow passage X, while the rest of the gas flow blown to the other part of the flow guide plate 20 is blocked by the flow guide plate 20, so that the rest of the gas flow cannot pass.

In the embodiments of the present disclosure, there is no particular limitation on a shape of the gas flow passage X formed in the body 21 of the flow guide plate 20 so long as a gas flow flows from one side to the other side of the flow guide plate 20 through the gas flow passage X while flow rates of portions of the gas flow at respective parts of the body 21 of the flow guide plate 20 are controlled by a size of the gas flow passage X.

The embodiments of the present disclosure provide a flow guide plate, a lower electrode assembly for a dry etching apparatus and a dry etching apparatus. A gas flow passage is formed in the flow guide plate so that a gas flow passes through the gas flow passage. A passage area per unit length of the gas flow passage formed in the body of the flow guide plate is gradually increased from a center towards both sides of the body of the flow guide plate. The flow guide plate formed with the gas flow passage is connected to a side of the lower electrode, so that a plasma gas flow flows across the lower electrode assembly of the dry etching apparatus in an up-down direction through the gas flow passage. Since the passage area per unit length of the gas flow passage formed in the body of the flow guide plate is gradually increased from the center towards both sides of the body of the flow guide plate, a flow rate of a portion of the plasma gas flow through a part of the gas flow passage closer to a gas suction opening and a flow rate of another portion of the plasma gas flow through another part of the gas flow passage farther from the gas suction opening are substantially uniform. Therefore, by controlling flow rates of portions of the gas flow at respective parts of the substrate, etch rates at which the respective parts of the substrate are etched are adjusted, thereby reducing a difference between the etch rates at which the respective parts of the substrate are etched, and increasing a uniformity of the etch rates.

Referring to FIG. 3 to FIG. 6, in embodiments of the present disclosure, the gas flow passage X comprises a plurality of through holes 22. The first position is a center of the body 21, and the second position is a position of the body away from the center of the body 21. According to an example of the present disclosure, the body 21 is a strip-shaped flat plate, for example a rectangle plate, and the first position and the second position are positions of the body 21 in a length direction of the body. For example, the first position is the center of the body, and the second position is two ends of the body 21 in the length direction of the body 21.

In some embodiments, referring to FIG. 3 to FIG. 6, a ratio of the passage area per unit length of at least the portion of the gas flow passage X formed in the body 21 to a total passage area of the plurality of through holes 22 is gradually increased in the direction from the first position to the second position. For example, as shown in FIG. 3, a ratio of a total passage area of through holes per unit length of the plurality of through holes 22 formed in the body 21 of the flow guide plate 20 to a total passage area of the plurality of through holes 22 is gradually increased from the center towards both sides of the body of the flow guide plate.

The flow guide plate 20 is a flat plate having a plurality of through holes 22. When a gas flow impacts on an upper surface of the flow guide plate 20, it can flow below a lower surface of the flow guide plate 20 through the plurality of through holes 22. By setting a ratio of a total passage area of through holes per unit length of the plurality of through holes 22 formed in the body 21 of the flow guide plate 20 to a total passage area of the plurality of through holes 22, proportions and flow rates of portions of the gas flow passing through respective parts of the body 21 of the flow guide plate 20 can be controlled. As shown in FIG. 3, a ratio of a total passage area of through holes per unit length of the plurality of through holes 22 formed in the body 21 of the flow guide plate 20 to a total passage area of the plurality of through holes 22 is set to be gradually increased from the center towards both sides of the body of the flow guide plate. Therefore, the flow rate of the gas flow remains substantially uniform from the center towards both sides of the body of the flow guide plate.

In some embodiments, as shown in FIG. 3, the plurality of through holes 22 have a same diameter, and a distribution density of the through holes per unit length of at least the portion of the gas flow passage X formed in the body 21 is gradually increased in the direction from the first position to the second position. For example, the distribution density of through holes per unit length of the plurality of through holes 22 formed in the body 21 of the flow guide plate 20 is gradually increased from the center towards both sides of the body of the flow guide plate.

In some embodiments, as shown in FIG. 3, the plurality of through holes 22 are arranged in one row along the length direction of the body 22, and the number of through holes per unit length of at least the portion of the gas flow passage X formed in the body 21 is gradually increased in the direction from the first position to the second position. For example, the number of through holes per unit length, in the length direction, of the plurality of through holes 22 formed in the body 21 of the flow guide plate 20 is gradually increased from the center towards both sides of the body of the flow guide plate.

As shown in FIG. 3, the plurality of through holes 22 have a same diameter T, and are arranged in one row along the length direction of the body of the flow guide plate. Each of dashed boxes in FIG. 3 indicates the unit length in the length direction of the body 21 of the flow guide plate 20. It can be known from FIG. 3 that there is only one through hole 22 in a unit length in a middle position of the flow guide plate 20, and the number of through holes 22 per unit length is gradually increased from two to three in the direction from the center towards an end of the body of the flow guide plate. Thereby, a flow rate of a portion of the gas flow in the middle position of the body of the flow guide plate 20 and flow rates of portions of the gas flow on both sides of the body of the flow guide plate 20 are substantially uniform.

According to an embodiment of the present disclosure, as shown in FIG. 4, the plurality of through holes 22 are arranged in a plurality of rows along the length direction of the body of the flow guide plate 20, and the number of rows of through holes per unit length or the number of through holes per unit length of at least the portion of the gas flow passage X formed in the body 21 is gradually increased in the direction from the first position to the second position. For example, as shown in FIG. 4, the number of rows of through holes per unit length, along the length direction, of the plurality of through holes 22 formed in the body 21 of the flow guide plate 20 is gradually increased from the center towards both sides of the body of the flow guide plate.

As shown in FIG. 4, the plurality of through holes 22 are arranged in a plurality of rows along the length direction of the body of the flow guide plate 20, there is only one row of through holes 22 in a middle position of the flow guide plate 20, and the number of rows of through holes per unit length of the plurality of through holes 22 is gradually increased from the center towards both sides of the body of the flow guide plate. The number of rows of through holes per unit length of the plurality of through holes 22 is maximal and is three at either side of the body of the flow guide plate. Each of dashed boxes in FIG. 4 indicates the unit length in the length direction of the body 21 of the flow guide plate 20. It can be known from FIG. 4 that there is only one through hole 22 or one row of through holes 22 in a unit length in a middle position of the flow guide plate 20, and the number of rows of through holes 22 per unit length and also a sum of through holes 22 per unit length are gradually increased in the direction from the center towards an end of the body of the flow guide plate. Therefore, the numbers of the through holes 22 are further adjusted by setting the numbers of the rows of the through holes 22, so that flow rates of portions of the gas flow at respective parts of the body 21 of the flow guide plate 20 are controlled and adjusted.

Furthermore, when the plurality of rows of through holes 22 are formed in the body 21 of the flow guide plate 20, two adjacent rows of through holes 22 may also be staggered, instead of alignment of positions, in the length direction of the body 21 of the flow guide plate 20, of the plurality of rows of through holes 22 with one another as shown in FIG. 4. Thereby, nonuniformity between flow rates of portions of the gas flow at parts of the substrate 30 corresponding to the through holes 22 and corresponding to positions, between the adjacent through holes 22, of the body of the flow guide plate is reduced.

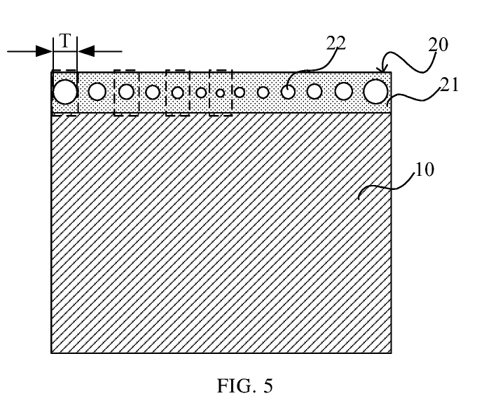

According to an embodiment of the present disclosure, as shown in FIG. 5, a distribution density per unit length of the plurality of through holes 22 in the body 21 is uniform, and diameters of through holes of at least the portion of the gas flow passage X formed in the body 21 are gradually increased in the direction from the first position to the second position. For example, a distribution density per unit length of the plurality of through holes 22 in the body of the flow guide plate 20 is uniform, and diameters T of the plurality of through holes 22 are gradually increased from the center towards both sides of the body of the flow guide plate.

As shown in FIG. 5, a plurality of through holes 22 are formed in the body 21 of the flow guide plate 20, distances between any two adjacent ones of the plurality of through holes 22 are uniform, and diameters T of the plurality of through holes 22 are different in sizes. A diameter T of one of the plurality of through holes 22 in a central position of the body of the flow guide plate 20 is minimal, the diameters T of the plurality of through holes 22 are gradually increased in the direction from the center towards both sides of the body of the flow guide plate, and diameters T of ones of the plurality of through holes 22 in both ends of the body of the flow guide plate 20 are maximal. Each of dashed boxes in FIG. 5 indicates the unit length in the length direction of the body 21 of the flow guide plate 20. It can be known from FIG. 5 that there is one through hole 22 in each dashed box, a diameter T of a through hole 22 in the dashed box in the central position of the body of the flow guide plate 20 is minimal, and diameters T of through holes 22 in the dashed boxes are gradually increased in a direction from the center towards an end of the body of the flow guide plate. Thereby, a flow rate of a portion of the gas flow in the middle position of the body of the flow guide plate 20 and flow rates of portions of the gas flow on both sides of the body of the flow guide plate 20 are substantially uniform.

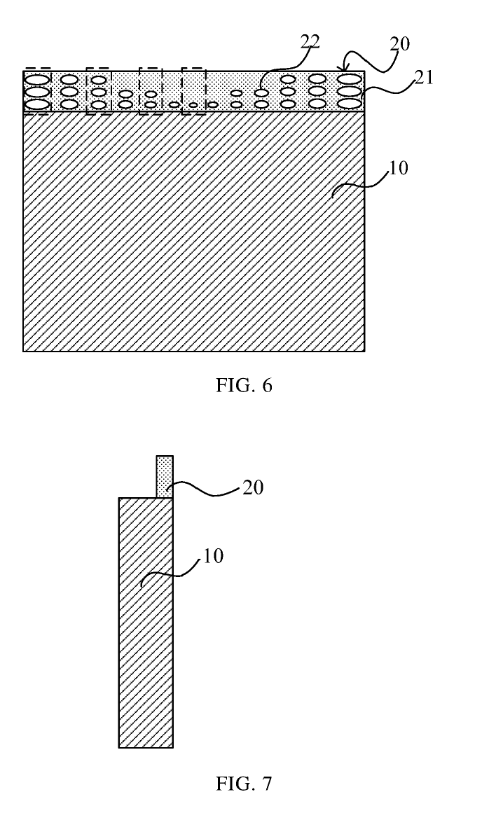

According to an embodiment of the present disclosure, as shown in FIG. 6, the plurality of through holes 22 are arranged in a plurality of rows along the length direction of the body 21, the number of rows of through holes 22 per unit length of at least the portion of the gas flow passage X formed in the body 21 is gradually increased in the direction from the first position to the second position, and diameters of through holes 22 of at least the portion of the gas flow passage X formed in the body 21 are gradually increased in the direction from the first position to the second position. For example, the number of rows of through holes per unit length, along the length direction of the body of the flow guide plate 20, of the plurality of through holes 20 is gradually increased from the center towards both sides of the body of the flow guide plate, and diameters T of the plurality of through holes 22 are gradually increased from the center towards both sides of the body of the flow guide plate.

As shown in FIG. 6, in this way, on one hand, by setting the number of rows of through holes per unit length of the plurality of through holes 22 to be gradually increased from the center towards both sides of the body of the flow guide plate 20, a total passage area of through holes per unit length of the plurality of through holes 22 in the central position of the body is less than a total passage area of through holes per unit length of the plurality of through holes 22 on both sides of the body, so that flow rates of portions of the gas flow passing through respective parts of the body 21 of the flow guide plate 20 can be adjusted and controlled. On the other hand, by setting the diameters T of the plurality of through holes 22 to be gradually increased from the center towards both sides of the body of the flow guide plate, a total passage area of through holes per unit length of the plurality of through holes 22 in the central position of the body is further less than a total passage area of through holes per unit length of the plurality of through holes 22 on both sides of the body, so that the flow rates of the portions of the gas flow passing through the respective parts of the body 21 of the flow guide plate 20 can also be further adjusted and controlled.

Furthermore, when the flow rates of the portions of the gas flow at the respective parts of the body 21 of the flow guide plate 20 also need to be further controlled, in the case where the diameters T of the plurality of through holes 22 are gradually increased from the center towards both sides of the body and the number of rows of through holes per unit length of the plurality of through holes 22 is gradually increased from the center towards both sides of the body, the distribution density of the through holes 22 is further set to vary, so that a distance between two adjacent through holes 22 in a central position of the body of the flow guide plate 20 is smaller, while a distance between two adjacent through holes 22 in both ends of the body of the flow guide plate 20 is greater.

According to an embodiment of the present disclosure, as shown in FIG. 5, a cross section of the through hole 22 has a circular shape. As shown in FIG. 6, a cross section of the through hole 22 has an elliptic shape.

When the cross section of the through hole 22 has the circular shape, on one hand, smoothness of a gas flow through the through hole 22 can be improved since the through hole 22 has the same diameter in all directions, and on the other hand, compared with a slotted through hole 22, a circular through hole 22 can reduce whistling noise which is possibly generated at the through hole 22 when a gas flow passes through the through hole.

According to an embodiment of the present disclosure, as shown in FIG. 5, a diameter T of the through holes 22 is less than or equal to 3 mm.

As shown in FIG. 5, when the diameters T of the through holes 22 in the body 21 of the flow guide plate 20 are different from one another, the diameters T of all of the through holes 22 are less than 3 mm.

In this way, a size of the diameter T of the through holes 22 is limited. Thereby, when a lower electrode assembly for a dry etching apparatus according to the embodiment of the present disclosure is applied inside a reaction chamber of a dry etching apparatus to etch a substrate 30, big foreign substances or particles which are possibly carried by gas as the gas flows inside the reaction chamber can be prevented by through holes 22 from entering a gas suction opening disposed inside the reaction chamber, avoiding a harm to the gas suction opening and even a damage to the apparatus.

On the other hand, embodiments of the present disclosure provide a lower electrode assembly for a dry etching apparatus. As shown in FIG. 2, the lower electrode assembly comprises a lower electrode 10, and the flow guide plate 20 according to any one of the above embodiments. The flow guide plate 20 is connected to a side of the lower electrode 10. For example, the flow guide plate 20 is connected to the side of the lower electrode 10 along a length direction of the flow guide plate.

According to embodiments of the present disclosure, the lower electrode 10 may have a plate-shaped integrated structure. For example, the lower electrode 10 comprises a tungsten layer, an upper insulating layer on the tungsten layer, and a lower insulating layer beneath the tungsten layer. The tungsten layer is configured to generate an electric potential of the lower electrode when a voltage is applied to the tungsten layer.

According to embodiments of the present disclosure, the lower electrode 10 has a plate-shaped integrated structure, while the flow guide plate 20 also has a strip-shaped flat plate structure. The flow guide plate 20 is disposed on a side of the lower electrode, and an upper surface of the flow guide plate 20 is flush with an upper surface of the lower electrode 10, and is located in a same horizontal plane as the upper surface of the lower electrode 10. As shown in FIG. 2, the lower electrode 10 is configured so that a substrate 30 to be etched is placed on the lower electrode, and the lower electrode 10 cooperates with an upper electrode to generate plasmas for etching the substrate 30. Generally, the lower electrode 10 has a quadrangular shape. Therefore, a side of the flow guide plate 20 along a length direction of the flow guide plate is connected to any one side of the lower electrode 10. As shown in FIG. 2, the flow guide plate 20 is connected to a side (namely a side located on an upper side in FIG. 2) of the lower electrode 10 along the length direction of the flow guide plate.

According to an embodiment of the present disclosure, as shown in FIG. 7, generally, the flow guide plate 20 has a relatively small thickness. In order to prevent the gas flow from generating vortex or noise at a junction between the flow guide plate 20 and the lower electrode 10, an upper surface of the flow guide plate 20 is flush with an upper surface of the lower electrode 10, and is located in a same horizontal plane as the upper surface of the lower electrode 10.

In the description of the present disclosure, it should be appreciated that orientations or positional relationships indicated by terms such as “center”, “central”, “upper”, “lower”, “left”, “right”, “vertical”, “horizontal” “top”, and “bottom” are based on orientations or positional relationships shown in the accompanying drawings, are merely used to facilitate the description of the present disclosure and simplification of the description, but do not indicate or imply that a device or an element of which an orientation or positional relationship is indicated must have the particular orientation and must be configured and operated in the particular orientation. Therefore, the orientations or positional relationships should not be construed to limit the present disclosure.

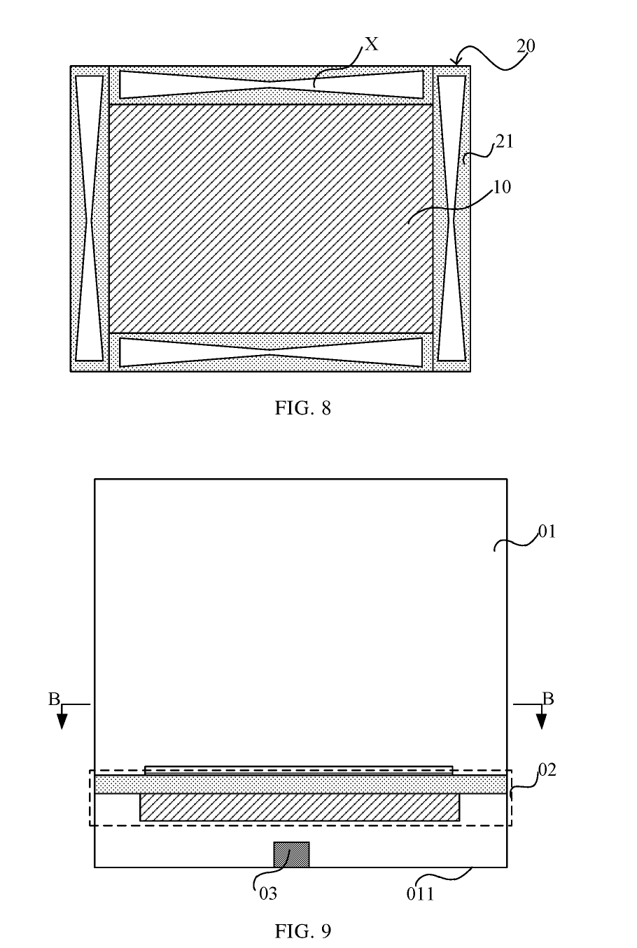

According to an embodiment of the present disclosure, as shown in FIG. 8, the flow guide plate 20 is disposed on each of four sides of the lower electrode 10.

In this way, gas flows on the four sides of the lower electrode 10 can be respectively adjusted and controlled by the distributions of the gas flow passages X formed in the bodies 21 of the flow guide plates 20 disposed on the four sides. Therefore, by adjusting and controlling the gas flows, gas flows at respective parts of the substrate 30 placed on the lower electrode 10 are uniform, thereby controlling and adjusting etch rates at which the respective parts of the substrate 30 are etched to be uniform.

According to embodiments of the present disclosure, the flow guide plate 20 is disposed on each of the four sides of the lower electrode 10. As shown in FIG. 8, each of two flow guide plates 20 along two first sides (two sides respectively located on upper and lower sides in FIG. 8) of the lower electrode 10 has a same length as a corresponding one of the two first sides, and each of two flow guide plates 20 along two second sides (two sides respectively located on left and right sides in FIG. 8) of the lower electrode 10 has a greater length than a corresponding one of the two second sides. Thereby, the four flow guide plates 20 disposed on the four sides of the lower electrode 10 surround the lower electrode 10, avoiding existence of a gap at a junction between any two adjacent flow guide plates 20. The flow guide plates 20 may also be disposed in other manners as long as it is ensured that no gap exists at the junction between any two adjacent flow guide plates 20.

Embodiments of the present disclosure further provide a dry etching apparatus. As shown in FIG. 9, the dry etching apparatus comprises: a housing 01 defining a reaction chamber; and the above lower electrode assembly 02 disposed inside the reaction chamber. The dry etching apparatus further comprises: an upper electrode; and a gas suction opening 03 formed in a bottom wall 011 of the housing 01 at a central position of a side of the bottom wall. The bottom wall has a polygonal shape, and has a plurality of sides. The bottom wall of the housing 01 is formed with the gas suction opening 03 at a first one of the plurality of sides of the bottom wall, and is formed with no gas suction opening 03 at a second one of the plurality of sides of the bottom wall. In the lower electrode assembly of the dry etching apparatus, a passage area per unit length of the gas flow passage formed in the body 21 of the flow guide plate 20 corresponding to the first one of the plurality of sides is less than a passage area per unit length of the gas flow passage formed in the body 21 of the flow guide plate 20 corresponding to the second one of the plurality of sides. According to embodiments of the present disclosure, a gas feed pump is disposed over the housing to blow gas towards the lower electrode, and a gas suction pump is disposed under the housing to pump plasma gas flow. By controlling a flow velocity at which the plasma gas flow flows past a surface of the substrate inside the reaction chamber, an etch rate at which the substrate is etched by ion bombardment can be controlled.

The upper electrode and the lower electrode 10 are disposed inside the reaction chamber in the housing 01 of the dry etching apparatus according to the embodiments of the present disclosure, and a substrate 30 is placed on an upper surface of the lower electrode 10.

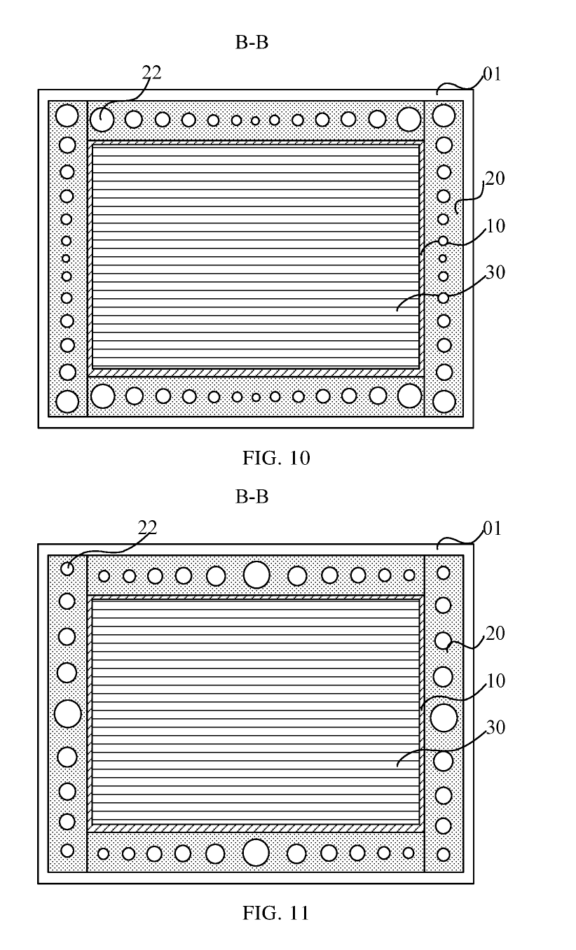

In an embodiment, the gas suction opening 03 is formed in the bottom wall of the housing 01 at a central position of each side of the bottom wall. As shown in FIG. 10, after processing gas is fed into the reaction chamber, a voltage is applied to the upper electrode and the lower electrode 10. The processing gas reacts to generate high-energy plasmas by an electric potential difference formed between the upper electrode and the lower electrode 10 under the action of an electric field. The high-energy plasmas bombard the substrate 30 at a high velocity, thereby etching the substrate 30. Gas in the reaction chamber is pumped through the gas suction opening 03 formed in the bottom wall of the housing 01 at the central position of each side of the bottom wall, so that the high-energy plasmas in the reaction chamber flow quickly, thereby increasing the etch rate. Generally, the gas suction opening 03 is formed in the bottom wall of the housing 01 at the central position of each side of the bottom wall due to an internal structure of the reaction chamber and a limitation of a volume of a gas suction device. As a result, a flow rate of a gas flow in a position of the reaction chamber closer to the gas suction opening 03 is greater, and a flow rate of a gas flow in a position of the reaction chamber farther from the gas suction opening 03 is smaller. In this case, etch rates at which respective parts of the substrate 30 are etched are not uniform due to different flow rates of gas flows at the respective parts of the substrate 30.

In the embodiments of the present disclosure, the flow guide plate 20 is disposed, and a ratio of a passage area, in each position of the body 21 of the flow guide plate 20, of the gas flow passage X formed in the body 21 of the flow guide plate 20 to a total passage area of the gas flow passage is set. For example, as shown in FIG. 10, diameters of the through holes 22 formed in the body 21 of the flow guide plate 20 corresponding to each side of the bottom wall are set to be gradually increased from the center towards both sides of the body of the flow guide plate, and a distribution density of the plurality of through holes 22 in the body 21 of the flow guide plate 20 is uniform. Thereby, the flow rate of the gas flow is substantially uniform at the center and both ends of the body 21 of the flow guide plate 20. Therefore, a difference of etch rates at which parts, corresponding to the side of the bottom wall, of the substrate 30 placed on the lower electrode 10 are etched is reduced.

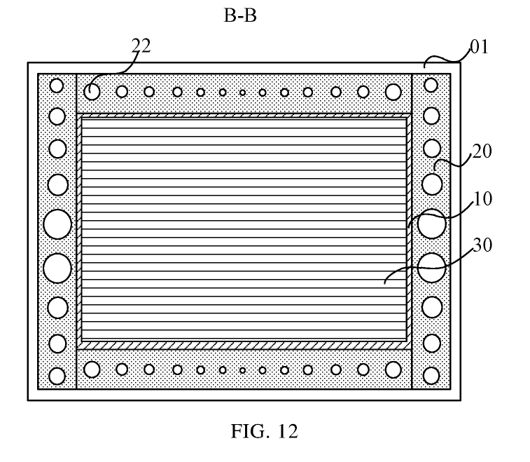

According to embodiments of the present disclosure, the housing 01 is formed with four gas suction openings 03 respectively located at four corners of the bottom wall of the housing 01. In this case, as shown in FIG. 11, the gas suction opening 03 is closer to the end of the flow guide plate 20 and is farther from the center of the flow guide plate 20. When the gas flow passage X formed in the body 21 of the flow guide plate 20 is through holes 22 having different diameters, the diameters of the through holes 22 formed in the body 21 of the flow guide plate 20 are gradually decreased from the center towards both sides of the body of the flow guide plate in order to alleviate the problem that the flow rate of the gas flow closer to the gas suction opening 03 is greater and the flow rate of the gas flow farther from the gas suction opening 03 is smaller.

According to embodiments of the present disclosure, the bottom wall of the housing 01 is formed with the gas suction opening 03 at a first one of the plurality of sides of the bottom wall, and is formed with no gas suction opening 03 at a second one of the plurality of sides of the bottom wall. As shown in FIG. 12, in the lower electrode assembly 02 of the dry etching apparatus, a passage area per unit length of the gas flow passage formed in the body 21 of the flow guide plate 20 corresponding to the first one of the plurality of sides is less than a passage area per unit length of the gas flow passage formed in the body 21 of the flow guide plate 20 corresponding to the second one of the plurality of sides.

According to embodiments of the present disclosure, the bottom wall of the housing 01 is formed with the gas suction opening 03 at a first one of four sides of the bottom wall, and is formed with no gas suction opening 03 at a second one of the four sides of the bottom wall. A pumping action generated, through the gas suction opening 3, in a position corresponding to the second one of the four sides is weaker than a pumping action generated, through the gas suction opening 3, in a position corresponding to the first one of the four sides. Therefore, in order to alleviate a difference between flow rates of gas flows at respective sides of the entire substrate 30 so that uniformity of an etch rate is improved as far as possible, the gas flow passage X formed in the body 21 of the flow guide plate 20 corresponding to the first one of the plurality of sides and the gas flow passage X formed in the body 21 of the flow guide plate 20 corresponding to the second one of the plurality of sides are set, respectively, so that a total passage area of the gas flow passage X formed in the body 21 of the flow guide plate 20 corresponding to the first one of the plurality of sides is less than a total passage area of the gas flow passage X formed in the body 21 of the flow guide plate 20 corresponding to the second one of the plurality of sides. Thereby, a flow rate of a gas flow through the gas flow passage formed in the body 21 of the flow guide plate 20 corresponding to the first one of the plurality of sides and a flow rate of a gas flow through the gas flow passage formed in the body 21 of the flow guide plate 20 corresponding to the second one of the plurality of sides are substantially uniform. In other words, the passage area of the gas flow passage X farther from the gas suction opening 03 is greater, and the passage area of the gas flow passage X closer to the gas suction opening 03 is smaller, so that flow rates of gas flows at respective parts of the substrate 30 are uniform.

In addition, according to embodiments of the present disclosure, as shown in FIG. 12, the bottom wall of the housing 01 of the dry etching apparatus is formed with the gas suction opening 03 at a central position of each of two first ones (two sides respectively located on upper and lower sides in FIG. 12) of four sides of the bottom wall, and is formed with no gas suction opening 03 at each of two second ones (two sides respectively located on left and right sides in FIG. 12) of the four sides of the bottom wall. A flow guide plate 20 which is a flat plate having a plurality of through holes 22 is taken as an example. A total passage area of the through holes 22 formed in the body 21 of the flow guide plate 20 corresponding to each of the two first sides is less than a total passage area of the through holes 22 formed in the body 21 of the flow guide plate 20 corresponding to each of the two second sides. In addition, a distribution of the plurality of through holes 22 formed in the body 21 of the flow guide plate 20 corresponding to each of the two second sides is opposite to a distribution of the plurality of through holes 22 formed in the body 21 of the flow guide plate 20 corresponding to each of the two first sides. In other words, a total passage area of through holes per unit length of the plurality of through holes 22 formed in the body 21 of the flow guide plate 20 corresponding to each of the two second sides is maximal at the central position of the body 21 of the flow guide plate 20, and is gradually decreased from the center towards both sides of the body of the flow guide plate, and a total passage area of through holes per unit length of the plurality of through holes 22 formed in the body 21 of the flow guide plate 20 corresponding to each of the two first sides is maximal at both ends of the body 21 of the flow guide plate 20, and is gradually increased from the center towards both sides of the body of the flow guide plate, thereby alleviating a difference between flow rates of gas flows at respective parts of the substrate 30.

The above contents are only the specific embodiments of the present disclosure. However, the protection scope of the present disclosure is not limited thereto. Changes or substitutions that can be easily conceived by any person skilled in the art within the technical scope disclosed in the present disclosure should be contained within the protection scope of the present disclosure. Therefore, the protection scope of the present disclosure should be defined by the protection scope of the claims.

What is claimed is:

1. A flow guide plate comprising:
a body; and
a gas flow passage which is formed in the body and through which a gas flow passes,
wherein at least a portion of the gas flow passage is located between a first position and a second position of the body, and a passage area per unit length of at least the portion of the gas flow passage is gradually increased in a direction from the first position to the second position.

2. The flow guide plate of claim 1, wherein:
the gas flow passage comprises a plurality of through holes.

3. The flow guide plate of claim 2, wherein:
the body is a strip-shaped flat plate, and the first position and the second position are positions of the body in a length direction of the body.

4. The flow guide plate of claim 3, wherein:
a ratio of the passage area per unit length of at least the portion of the gas flow passage formed in the body to a total passage area of the plurality of through holes is gradually increased in the direction from the first position to the second position.

5. The flow guide plate of claim 3, wherein:
the plurality of through holes have a same diameter, and a distribution density of through holes per unit length of at least the portion of the gas flow passage formed in the body is gradually increased in the direction from the first position to the second position.

6. The flow guide plate of claim 3, wherein:
the plurality of through holes are arranged in one row along the length direction of the body, and a number of through holes per unit length of at least the portion of the gas flow passage formed in the body is gradually increased in the direction from the first position to the second position.

7. The flow guide plate of claim 3, wherein:
the plurality of through holes are arranged in a plurality of rows along the length direction of the body, and a number of rows of through holes per unit length of at least the portion of the gas flow passage formed in the body is gradually increased in the direction from the first position to the second position.

8. The flow guide plate of claim 3, wherein:
a distribution density per unit length of the plurality of through holes in the body is uniform, and diameters of through holes of at least the portion of the gas flow passage formed in the body are gradually increased in the direction from the first position to the second position.

9. The flow guide plate of claim 3, wherein:
the plurality of through holes are arranged in a plurality of rows along the length direction of the body, a number of rows of through holes per unit length of at least the portion of the gas flow passage formed in the body is gradually increased in the direction from the first position to the second position, and diameters of through holes of at least the portion of the gas flow passage formed in the body are gradually increased in the direction from the first position to the second position.

10. The flow guide plate of claim 3, wherein:
the first position is a center of the body, and the second position is one of two ends of the body in the length direction of the body.

11. A lower electrode assembly for a dry etching apparatus, the lower electrode assembly comprising:
a lower electrode; and
the flow guide plate according to claim 1, wherein the flow guide plate is connected to a side of the lower electrode.

12. The lower electrode assembly of claim 11, wherein:
the lower electrode assembly comprises four said flow guide plates respectively disposed on four sides of the lower electrode.

13. A dry etching apparatus comprising:
a housing defining a reaction chamber; and
the lower electrode assembly according to claim 11, disposed inside the reaction chamber.

14. The dry etching apparatus of claim 13, further comprising:
a gas suction opening formed in a bottom wall of the housing at a central position of a side of the bottom wall.

15. The dry etching apparatus of claim 14, wherein:
the bottom wall has a polygonal shape, and has a plurality of sides, and the body is a strip-shaped flat plate.

16. The dry etching apparatus of claim 15, wherein:
the bottom wall of the housing is formed with the gas suction opening at a first one of the plurality of sides of the bottom wall, and is formed with no gas suction opening at a second one of the plurality of sides of the bottom wall; and
in the lower electrode assembly of the dry etching apparatus, a passage area per unit length of the gas flow passage formed in the body of the flow guide plate corresponding to the first one of the plurality of sides is less than a passage area per unit length of the gas flow passage formed in the body of the flow guide plate corresponding to the second one of the plurality of sides.
